(19) United States
(12) Patent Application Publication
(10) Pub. No.: US 2015/0263231 A1
(43) Pub. Date: Sep. 17, 2015

(54) OPTICAL SEMICONDUCTOR DEVICE, DRIVING METHOD THEREOF, AND OPTICAL COHERENCE TOMOGRAPHY APPARATUS HAVING THE OPTICAL SEMICONDUCTOR DEVICE

(71) Applicant: CANON KABUSHIKI KAISHA, Tokyo (JP)

(72) Inventor: Yoshinobu Sekiguchi, Machida-shi (JP)

(73) Assignee: CANON KABUSHIKI KAISHA, Tokyo (JP)

(21) Appl. No.: 14/432,113

(22) PCT Filed: Sep. 24, 2013
(86) PCT No.: PCT/JP2013/076460

§ 371 Date: Mar. 27, 2015

(30) Foreign Application Priority Data
Sep. 28, 2012 (JP) 2012-215767

(51) Int. Cl. H01L 33/24; H01S 5/042; H01L 33/38; G01B 9/02; H01L 33/06; H01L 33/30

(52) U.S. Cl. CPC H01L 33/24; H01L 33/06; H01L 33/30; H01L 33/38; G01B 9/02091; H01S 5/042

(57) ABSTRACT

The present invention provides an optical semiconductor device which can make a wavelength band of emitted light wider than that of a conventional optical semiconductor device. The optical semiconductor device includes: an active layer including a multiple quantum well structure; and at least one electrode pair for injecting an electric current into the active layer, wherein the multiple quantum well structure has a first quantum well and a second quantum well which is different from the first quantum well, and the first quantum well and the second quantum well are mutually different in at least two out of a composition of a well layer, a width of the well layer, and a composition of a barrier layer.

### TECHNICAL FIELD

The present invention relates to an optical semiconductor device, a driving method thereof, and an optical coherence tomography apparatus having the optical semiconductor device.

### BACKGROUND ART

Conventionally, an optical coherence tomography (which may be simply referred to as OCT, hereafter) apparatus is known as an apparatus for acquiring an optical tomographic image of a living tissue. The OCT is a method of dividing a low coherence light which has been ejected from an optical source into measuring beams and reference beams, then multiplexing and the reference beams and a reflected beam from a measured object that corresponds to the measuring beams that have irradiated the object the reflected thereby, and acquiring a tomographic image of the object from the intensity of interfering beams of the reflected beam and the reference beams.

As an optical source for the OCT, a super luminescent diode (SLD) is used which is one of the optical semiconductor devices. In addition, it is desired to widen the wavelength band of the emitted light. Japanese Patent application Laid-Open No. 2009-283736 (hereafter referred to as Patent Document 1) proposes an optical semiconductor device that has a plurality of quantum well layers formed therein of which the wavelengths of the emitted light are different from each other, as a unit for widening the wavelength band of the emitted light. The optical semiconductor device disclosed in Patent Document 1 employs an active layer which has a multiple quantum well structure formed of a plurality of quantum wells of which the well widths are different from each other by 2 to 6 nm, and thereby widens a wavelength band of the emitted light.

### CITATION LIST

### Patent Literature

PTL 1: Japanese Patent Application Laid-Open No. 2009-283736

### SUMMARY OF INVENTION

### Technical Problem

However, the optical semiconductor device disclosed in the above described Patent Document 1 has a structure in which only well widths are mutually different among the plurality of the quantum well layers that constitute the multiple quantum well structure, and accordingly has had a limit in broadening the wavelength band of the emitted light.

With respect to the above described problem, an object of the present invention is to provide an optical semiconductor device which can make the wavelength band of the emitted light wider than that of a conventional optical semiconductor device.

### Solution to Problem

An optical semiconductor device according to the present invention is an optical semiconductor device which includes: an active layer including a multiple quantum well structure; and at least one electrode pair for injecting an electric current into the active layer, wherein the multiple quantum well structure has a first quantum well and a second quantum well which is different from the first quantum well, and the first quantum well and the second quantum well are mutually different in at least two out of a composition of a well layer, a width of the well layer, and a composition of a barrier layer.

An optical coherence tomography apparatus according to the present invention includes: an optical source section having the optical semiconductor device; a specimen measuring section of irradiating a specimen with light emitted from the optical source section and transmitting a reflected beam from the specimen; a reference section of irradiating a reference mirror with the light emitted from the optical source section and transmitting a reflected beam from the reference mirror; an interference section of making the reflected beam from the specimen measuring section and the reflected beam from the reference section interfere with each other; a photodetector section for detecting the interfering beams from the interference section; and an image processing section for obtaining a tomogram of the specimen based on an intensity of the interfering beams which have been detected in the photodetector section.

A driving method of an optical semiconductor device according to the present invention includes injecting an electric current into the active layer in the optical semiconductor device, wherein injecting includes adjusting an amount of the electric current to be injected into the active layer so as to cause light emission from the first quantum well at the ground level and the first quantum level, and so as to provide the peak of the light emitted from the ground level of the second quantum well within the full width at half maximum of the peak of the light emitted from the ground level of the first quantum well.

Further features of the present invention will become apparent from the following description of exemplary embodiments with reference to the attached drawings.

### BRIEF DESCRIPTION OF DRAWINGS

FIG. 1 is a view illustrating an energy band of an active layer portion in a first embodiment of the present invention.

FIG. 2 is a view illustrating an emission spectrum of a single quantum well SLD which employs, as an active layer, only a first quantum well in the first embodiment of the present invention.

FIG. 3 is a view illustrating an emission spectrum of a single quantum well SLD which employs a second quantum well in the first embodiment of the present invention as an active layer.

FIG. 4 is a view illustrating an emission spectrum of an SLD which employs two quantum wells of the first and the second quantum wells in the first embodiment of the present invention as an active layer.

FIG. 5 is a view illustrating an energy band of an active region of Exemplary Embodiment 2 of the present invention.

FIG. 6 is a view illustrating an emission spectrum in Exemplary Embodiment 2 of the present invention.

FIG. 7 is a view illustrating a cross-sectional structure of a super luminescent diode (SLD) in Exemplary Embodiment 1 of the present invention.

FIG. 8 is a perspective view of the super luminescent diode (SLD) in Exemplary Embodiment 1 of the present invention.

FIG. 9 is a perspective view of a double-electrode structured SLD in a second embodiment and Exemplary Embodiment 3 of the present invention.

FIG. 10 is a view illustrating an emission spectrum appearing when an electric current has been injected into an electrode in a light-emitting side in the second embodiment and Exemplary Embodiment 3 of the present invention.

FIG. 11 is a view illustrating an emission spectrum in Exemplary Embodiment 3 of the present invention.

FIG. 12 is a schematic view describing a structure example of an optical coherence tomography apparatus (OCT apparatus) which employs a super luminescent diode (SLD), in Exemplary Embodiment 4 of the present invention for an optical source.

### DESCRIPTION OF EMBODIMENTS

The optical semiconductor device in embodiments of the present invention has an active layer including a multiple quantum well structure and at least one electrode pair for injecting an electric current into the active layer therethrough, and the multiple quantum well structure has a first quantum well and a second quantum well which is different from the first quantum well. Furthermore, the first quantum well and the second quantum well are mutually different in at least two items selected from a composition of a well layer, a width of the well layer, and a composition of a barrier layer.

A plurality of quantum wells which are mutually different in any one item selected from the composition of the well layer, the width of the well layer and the composition of the barrier layer emit light each in different wavelength regions. Therefore, when the quantum wells are mutually different in at least two items selected from the composition of the well layer, the width of the well layer, and the composition of the barrier layer, a wavelength region of emitted light can be much widened.

The first quantum well can be configured to emit light at a ground level and a first quantum level, and the second quantum well can be configured so that a peak of the light emitted from the ground level of the second quantum well exists within the full width at half maximum of a peak of the light emitted from the ground level of the first quantum well. Here, when a high electric current is injected into an active layer the intensity of the light emitted from the ground level of the first quantum well is generally small compared to the intensity of the light emitted at the first quantum level. Because of this, light emitted from the ground level of the first quantum well having a small intensity of emitted light can be amplified and the intensity of the emitted light can be increased, because the peak of the light emitted from the ground level of the second quantum well exists within the full width at half maximum of the peak of the light emitted from the ground level of the first quantum well. The lights emitted from the ground level of the first and the second quantum wells are superposed, and the resultant intensity of the emitted light increases. Thereby, a sufficient intensity of the emitted light is obtained from the ground level even when a large amount of an electric current is injected, and an optical semiconductor device is realized which has a broad wavelength band of the emitted light.

When the compositions of the well layers are mutually different, the wavelength region of the emitted light tends to be more changeable compared to the case where the barrier layers are mutually different. Because of this, the first quantum well and the second quantum well can be different in the composition of the well layer.

On the other hand, as the difference between the widths of the well layers becomes large, the difference between the intensities of the emitted lights from each of the quantum wells becomes large. Because of this, when it is desired to decrease the undulations of an emission spectrum to be finally output, the difference between the widths of the well layers can be small. For instance, the first quantum well and the second quantum well can be different in the width of the well layer, and the difference between the widths can be 1 nm or less.

When the first quantum well and the second quantum well are different in the composition of the well layer and the width of the well layer, the wavelength band of the emitted light can be widened by making the compositions of the well layers different from each other, and the power of emitted light can be adjusted by making the widths of the well layers different from each other.

In addition, the ground levels of each of the first quantum well and the second quantum well have a heavy positive hole and a light positive hole, and a peak of light emitted from the heavy positive hole of the second quantum well can exist within the full width at half maximum of a peak of light emitted from the heavy positive hole of the first quantum well. This is because the intensity of the light emitted from the heavy positive hole of the first quantum well becomes small when a high electric current is injected into a active layer, and consequently when the peak of the light emitted from the heavy positive hole of the second quantum well is made closer to the peak of the light emitted from the first quantum well, the intensity of the emitted light can be increased. In addition, in the first quantum well and the second quantum well, the well layers can have InₓGa₁₋ₓAs (0<x<1).

The optical semiconductor device according to the present embodiment may have such a structure that at least one electrode of the electrode pair is divided, and that the divided electrodes independently inject respective electric currents into a plurality of different regions in the active layer, the detail will be described later. Such a structure may be referred to as an optical multielectrode semiconductor device.

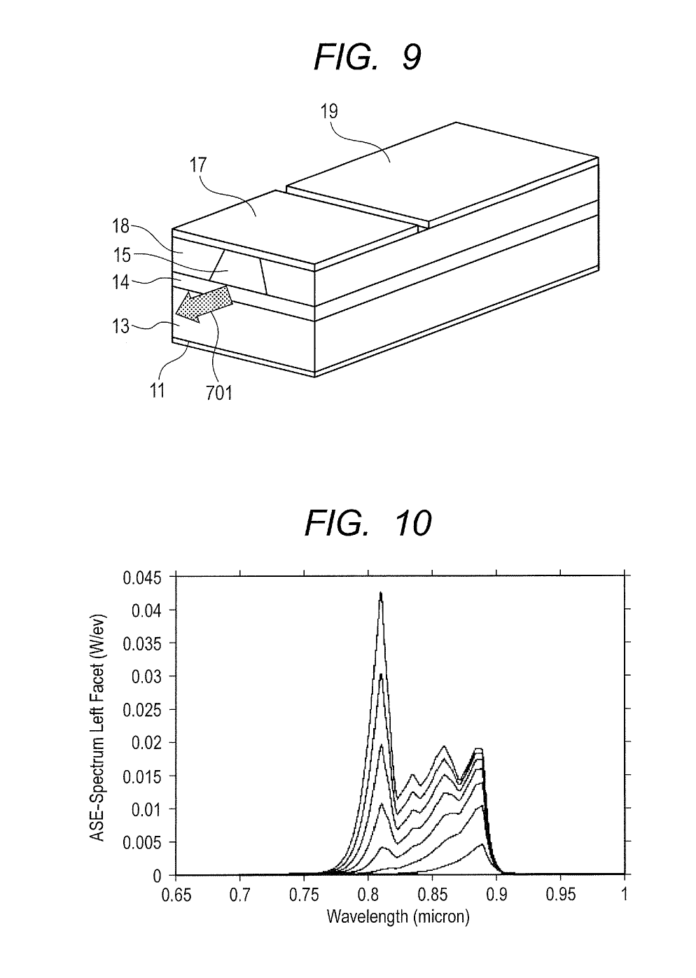

“At least one electrode of the electrode pair is divided” means that at least one electrode is divided into an electrode 17 and an electrode 19 as is illustrated in FIG. 9. In such a structure, the electric currents can be independently injected into a region between the electrode 17 and an electrode 11, and a region between the electrode 19 and the electrode 11, respectively.

Thus, when the wavelengths of the respective peaks of the lights emitted from the ground levels of the two different quantum wells are set within the full width at half maximum of the respective peaks of the emitted lights, the sufficient intensity of the emitted light is obtained from the ground level even at the time of high output, and an SLD having a broadband spectrum can be realized.

When the SLD having the broadband spectrum is used as an optical source of an OCT, the OCT enables observation with high resolution in a depth direction.

Hereafter, specific embodiments will be described in detail with reference to the drawings. In descriptions for the following embodiments, the parameters will be set for the sake of describing the embodiments comprehensibly, and the present invention is not limited by the parameters.

### First Embodiment

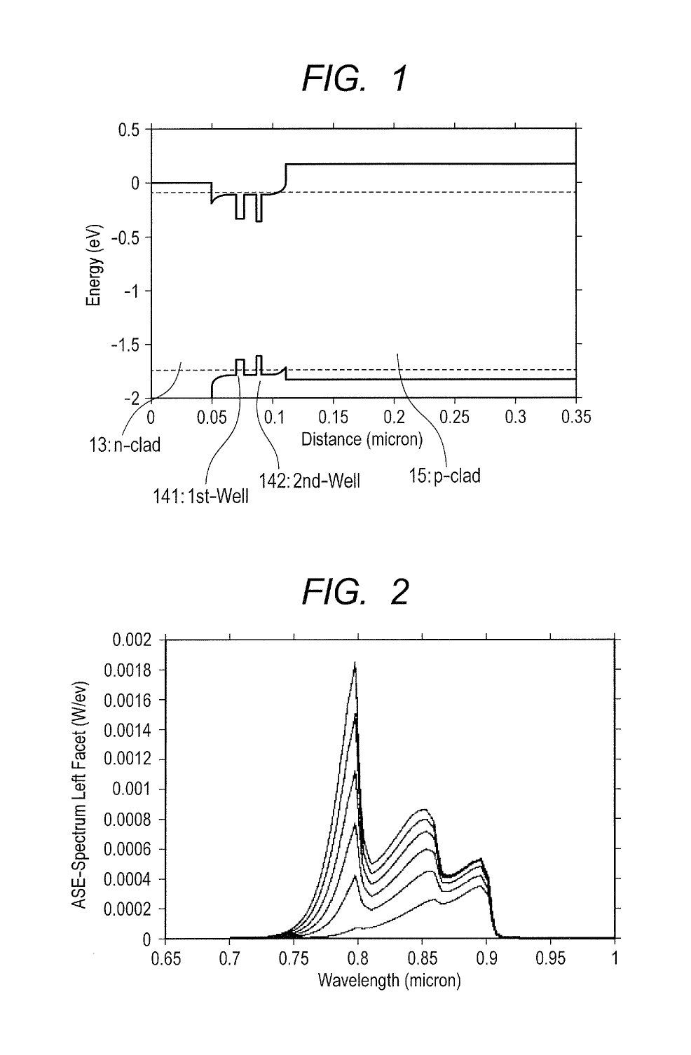

FIG. 1 is a view of an energy band of an active layer portion in a first embodiment, and the energy band has two quantum wells of the first and the second wells. FIG. 2 is an emission spectrum of a single quantum well SLD which is configured so that the first quantum well structure employs In_{0.11}Ga_{0.89}As; 7 nm as a well layer and employs Al_{0.2}Ga_{0.8}As as a barrier layer. In FIG. 2, peaks of the emitted light are: peaks of light emitted from a heavy positive hole of a ground level, light emitted from a light positive hole of a ground level and light emitted from a heavy positive hole of a first quantum level, respectively from a long wavelength side.

In FIG. 2, spectra caused by different injection currents are drawn so as to be superimposed, and when the level of the injected current is low, the spectrum has a peak of emitted light in a long wavelength, but as the injected current increases, the peak at which the intensity of the emitted light becomes the maximum is shifted to light emitted from the heavy positive hole of the ground level, light emitted from the light positive hole of the ground level, and light emitted from the heavy positive hole of the first quantum level. When a high electric current has been injected which leads to a high power, the light emitted from the heavy positive hole of the first quantum level becomes dominant, and the emission spectrum shows the peak which leans to the short wavelength side.

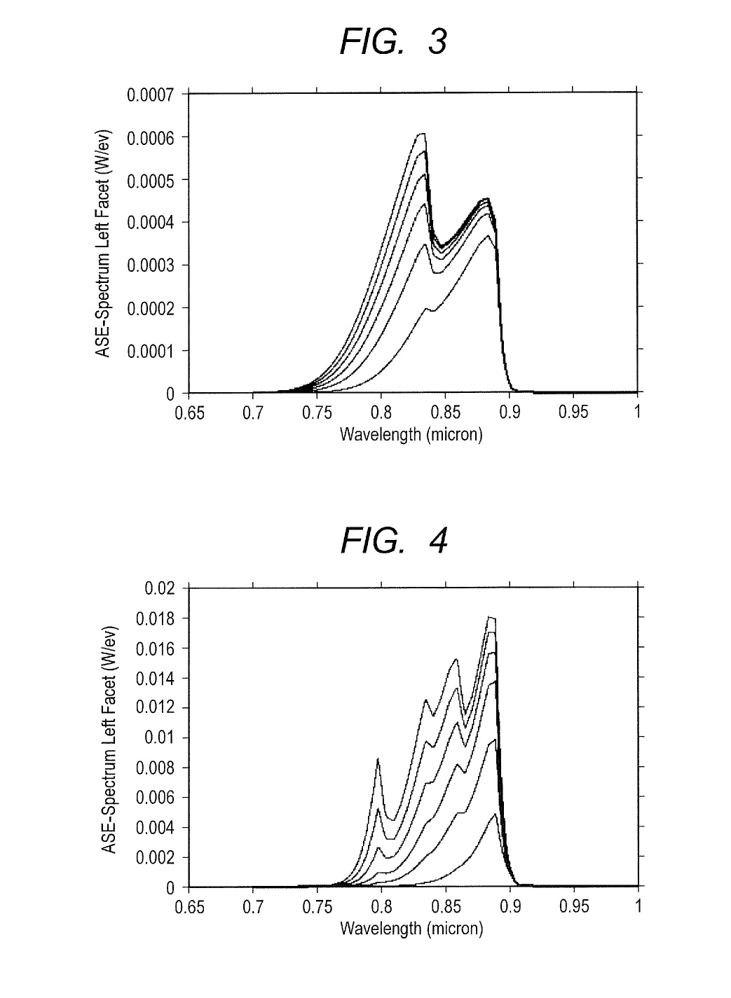

FIG. 3 is an emission spectrum of a single quantum well SLD which is configured so that the second quantum well structure employs In_{0.16}GaAs; 4 nm as a well layer, and employs Al_{0.2}Ga_{0.8}As as a barrier layer. The single quantum well SLD deepens the potential energy of the well by increasing an In composition of the well layer compared to that in the first quantum well structure, and also adjusts the energy of the quantum level by narrowing the width of the well. Thereby, the single quantum well SLD arranges the peak of light emitted at the ground level within the full width at half maximum of the peak of light emitted at the ground level of the first quantum well structure (FIG. 2). Incidentally, in the second quantum well structure, light emitted from the first quantum level does not exist in the quantum well.

FIG. 4 is an emission spectrum of an SLD which has two quantum wells of the first and the second wells, as an active layer. Because the lights emitted from the heavy positive holes of the ground levels of two quantum wells almost overlap (almost match), the intensity of emitted light increases, and at the same time because the wavelengths of lights emitted from the light positive holes of the ground levels are slightly different, a large dip is not formed in the emission spectrum. Furthermore, because injected carriers are distributed to two quantum wells, the light decreases which has been emitted from the heavy positive hole of the first quantum level and has projected due to the state of high injection in the case of the single quantum well structure (see FIG. 2), and a spectrum with small unevenness over a wide wavelength of the emitted light is obtained.

### Second Embodiment

As a second embodiment, a driving method will be described which enables the emission of light 701 having a broadband spectrum in double-electrode structured SLD illustrated in FIG. 9. FIG. 10 is an emission spectrum appearing when an electric current has been injected into an electrode of the light-emitting side. In the case of low injection, the light emitted from the ground level is dominant, but in the case of high injection by which a high power is obtained, the light emitted from the first quantum level becomes dominant, and a spectral bandwidth results in decreasing. Then, high current injection is applied to the electrode (front electrode) of the light-emitting side to obtain the high power. In this condition, the front electrode part is in such a state that an electric current having a high current density is injected thereinto, and the resultant spectrum shows that the light emitted from the heavy positive hole of a primary level is dominant. In this state, low current injection is applied to the other electrode (rear electrode) to set the electrode at such a state that an electric current having a low current density is injected thereinto and the light emitted from the ground level becomes dominant. In this state, the emitted light is incident on the front electrode part, in which the light emitted from the ground level is dominant, which has been generated in the rear electrode part, thereby induction amplification occurs, and the light having the increased intensity of the light emitted from the ground level is output from the light-outputting side. In other words, the spectrum is superimposed in which the emitted light has been induction-amplified in which the light generated in the rear electrode part and emitted from the ground level is dominant, on the spectrum in which the light emitted from the heavy positive hole of the primary level is dominant, which is obtained by the current injection into the front electrode. Thereby, the emitted light having the high power and showing the broadband spectrum is obtained.

In order to realize the above described driving, the front electrode part needs to maintain the spectrum in which the light emitted from the heavy positive hole of the primary level is dominant, and the rear electrode needs to maintain the spectrum in which the light emitted from the ground level is dominant, within the range of required light output. Lengthening the rear electrode part is effective for maintaining the spectrum in which the light emitted from the ground level is dominant. When a response speed becomes insufficient due to the lengthened rear electrode, high speed driving is enabled by continuously energizing the rear electrode and modulation-driving only the front electrode. For information, it is also possible to realize functions of the front electrode and the rear electrode by preparing a plurality of electrodes (current injection region), respectively.

(OCT)

An optical coherence tomography apparatus (OCT) according to the embodiment of the present invention has an optical source section having an optical semiconductor device according to the above described present embodiments. In addition, the apparatus has a specimen measuring section which irradiates the specimen with light from the optical source section and transmits the reflected beam from the specimen, and a reference section which irradiates a reference mirror with light from the optical source section and transmits the reflected beam from the reference mirror. Furthermore, the apparatus has an interference section which makes the reflected beam from the specimen measuring section interfere with the reflected beam from the reference section, a photodetector section which detects interfering beams from the interference section, and an image processing section which obtains a tomogram of the specimen based on the intensity of the interfering beams which have been detected at the photodetector section. The optical semiconductor device according to the present embodiment has a broad wavelength band of the emitted light, and accordingly when the device has been used as the optical source for OCT, the apparatus shows high depth resolution.

(Driving Method of Optical Semiconductor Device)

A driving method of the optical semiconductor device according to the present embodiment includes injecting an electric current into the active layer and making the first quantum well emit light at the ground level and the first quantum level. The driving method further includes adjusting the amount of an electric current to be injected into the active layer so that the intensity of light emitted from the ground level in the second quantum well exists within the full width at half maximum of the peak of light emitted from the ground level of the first quantum well. As described above, the peak of light emitted from the ground level in the second quantum well is adjusted so as to exist within the full width at half maximum of the peak of light emitted from the ground level of the first quantum well, and thereby the light emitted from the ground level of the first quantum well having a small peak of emitted light can be amplified to increase the intensity of the emitted light.

In addition, the driving method in the case of having used the optical semiconductor device having the above described multielectrodes includes injecting an electric current so that the light emitted from the primary level becomes dominant in the region in the light-emitting end side of the optical semiconductor device among a plurality of different regions to which the electric current is injected. Here, the region in the light-emitting end side is a region into which an electric current is injected by the electrode 17 and the electrode 11 in FIG. 9. In addition, the driving method includes injecting an electric current into another current injection region than that in the light-emitting end side so that the light emitted from the ground level becomes dominant. Here, another region than that in the light-emitting end side is a region into which an electric current is injected by the electrode 19 and the electrode 11 in FIG. 9. Incidentally, the number of the other regions than that in the light-emitting end side is only one in FIG. 9, but when the optical semiconductor device has other electrodes than the electrode 17 and the electrode 19, or when the optical semiconductor device has increased regions into which an electric current is independently injected by further dividing the electrode 17 and the electrode 19, the other regions mean other regions than the region closest to the light-emitting end.

In addition, since injection of current to the light-emitting end enables a control of the intensity of the emitted light, a rapid driving is enabled by injecting modulated current to this region.

### Exemplary Embodiment

Exemplary embodiments according to the present invention will be described below.

### Exemplary Embodiment 1

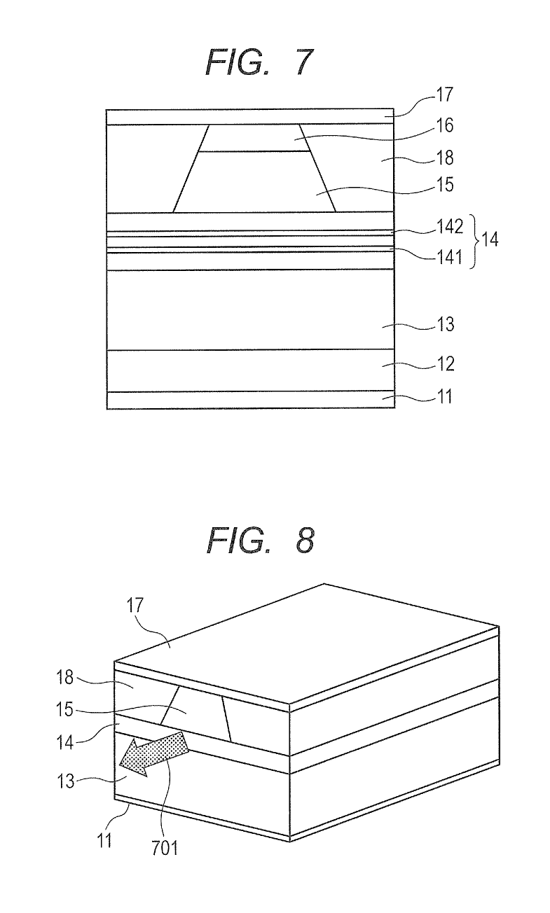

As Exemplary Embodiment 1, a structure example of a super luminescent diode (SLD) to which the present invention has been applied will be described with reference to FIG. 7. As is illustrated in FIG. 7, an n-cladding layer 13 formed of n-type Al_{0.7}Ga_{0.3}As and an MQW active region 14 are stacked on an n-type GaAs substrate 12. The MQW (Multi Quantum Well) active region 14 has a well layer InGaAs; 7 nm, which is the first quantum well structure 141, and a well layer InGaAs; 4 nm, which is a second quantum well structure 142. On the MQW active region 14, a p-type electrode 17 is formed through a p-cladding layer 15 formed of p-type Al_{0.7}Ga_{0.3}As and a contact layer 16 formed of GaAs. In addition, an n-type electrode 11 is formed on the back side of the n-GaAs substrate 12. The high-resistance layer 18 is formed to converge the current to the p-cladding layer 15. A material having a small refractive index can be used such that the light is confined in the active layer under the p-cladding layer 15. A layer of air can be used for the high-resistance layer 18

FIG. 8 is a perspective view of FIG. 7. A ridge stripe is tilted with respect to an end face by up to 7° to minimize the reflection, and also a protection film is formed on the end face. In FIG. 8, the same reference numerals will be put on the same members as those in FIG. 7, and detailed description will be omitted. In the emission spectrum (FIG. 4) of the light 701 which is obtained from the light-emitting end side by energization between p-n electrodes, the spectrum changes to the light emitted from the ground level and to the light emitted from the primary level, according to the increase of the injected current.

The first quantum well layer and the second quantum well layer are different in the composition of In and a well width. The second quantum well structure deepens the potential energy of the well by increasing the In composition of the well layer compared to that of the first quantum well structure 141, and adjusts the energy at the quantum level by narrowing the well width. Because the lights emitted from the heavy positive holes of the ground levels of two quantum wells almost overlap, the intensity of the emitted light increases, and at the same time because the wavelengths of the lights emitted from the light positive holes of the ground levels are different, a large dip is not formed in the emission spectrum. Furthermore, because injected carriers are distributed to two quantum wells, the light decreases which has been emitted from a heavy positive hole of a first quantum level and has projected due to the state of high injection in the case of the single quantum well structure, and a spectrum with small unevenness over a wide wavelength of the emitted light is obtained. The peak of light emitted from the heavy positive hole of the second ground level is arranged within the full width at half maximum of the peak of light emitted from the heavy positive hole of the ground level of the first quantum well structure 141, thereby the light emitted from the ground level is increased, and a broad emission spectrum is obtained. Incidentally, the spectrum bandwidth of the present exemplary embodiment is 0.8 to 0.9 μm, but it is also possible to obtain the spectrum bandwidth of 1.0 to 1.1 μm by selecting the In composition and the well width of InₓGa₁₋ₓAs quantum well layer which constitutes the quantum well active layer, and an Al composition of an Al_{y}Ga_{1-y}As barrier layer.

### Exemplary Embodiment 2

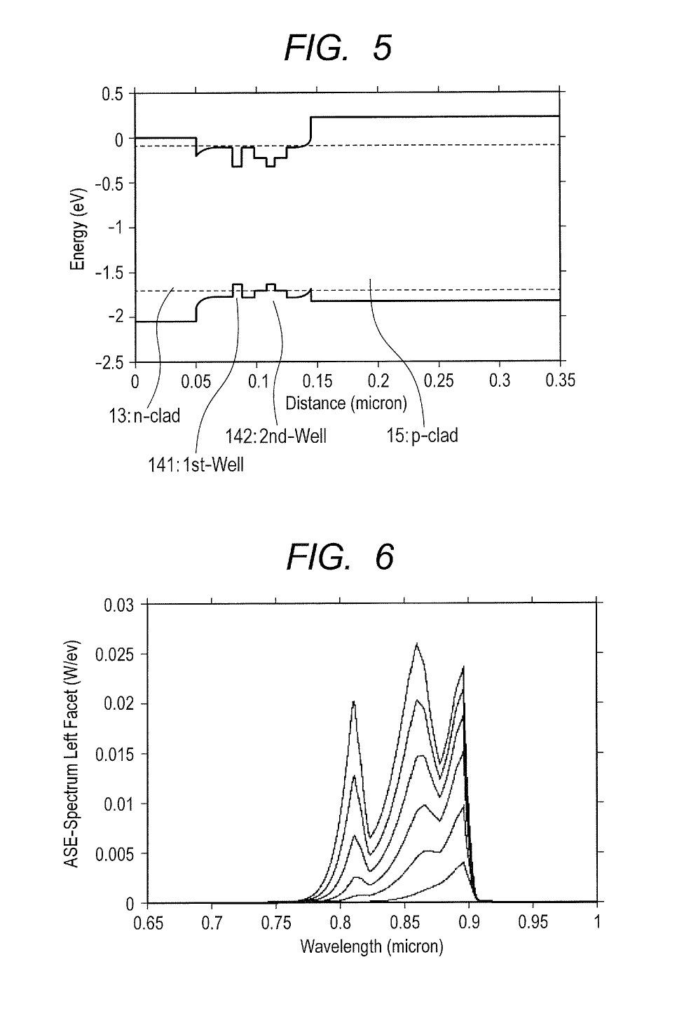

FIG. 5 is a view of an energy band of an active layer portion of Exemplary Embodiment 2.

The first quantum well structure 141 is configured to employ In_{0.11}GaAs: 8 nm as a well layer and employ Al_{0.2}Ga_{0.8}As as a barrier layer.

In addition, the second quantum well structure 142 is configured to employ In_{0.09}GaAs: 7 nm as a well layer and employ Al_{0.05}GaAs as a barrier layer.

The exemplary embodiment is configured so that the peaks of lights emitted at the ground levels exist mutually within the full width at half maximum, by controlling the well layer compositions, the well widths and the barrier heights of the first and the second quantum well structures 141 and 142.

Also in the second quantum well structure 142, the first quantum level does not exist in the quantum well.

An emission spectrum of the SLD of Exemplary Embodiment 2 is illustrated in FIG. 6. Because the wavelengths of the lights emitted from the light positive holes of the ground levels of two quantum wells are close to each other, an emission spectrum having a peak in the center of the emission spectrum is obtained. Other structures and functions are the same as those in Exemplary Embodiment 1, and description thereof will be omitted.

### Exemplary Embodiment 3

As Exemplary Embodiment 3, a structure example of a super luminescent diode (SLD) corresponding to the second embodiment will be described with reference to FIG. 9. In FIG. 9, the same reference numerals will be put on the same members as those in FIG. 7 and FIG. 8, and detailed description will be omitted.

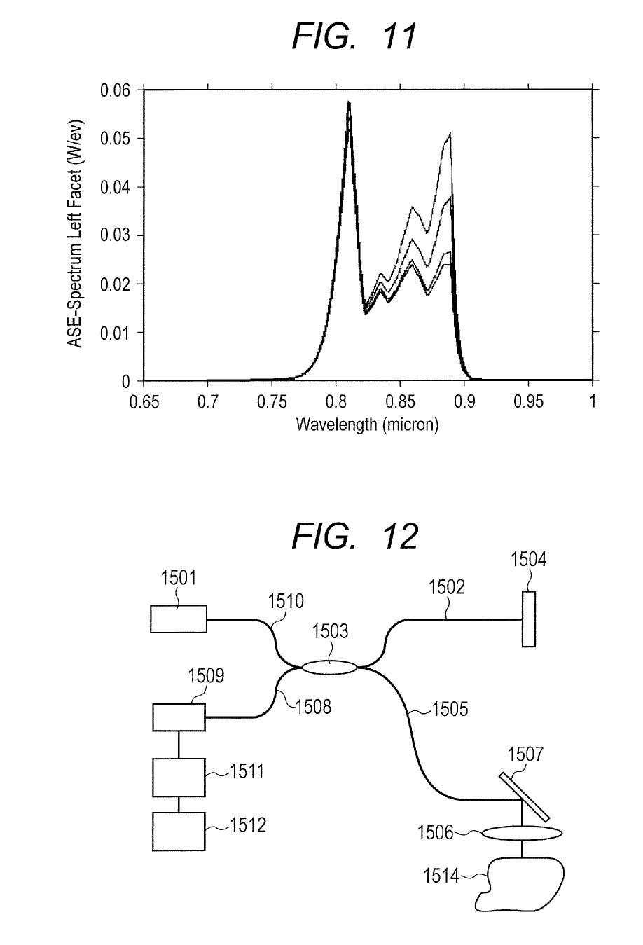

FIG. 9 is a schematic perspective view of the SLD in Exemplary Embodiment 3. The SLD is different from that in Exemplary Embodiment 1 in a point that the p-type electrode is formed of 2 electrodes. The size of the electrode of the light-emitting side (front electrode) is 0.7 mm, and the size of the other electrode (rear electrode) is 1.5 mm. In FIG. 11, spectra caused by different currents which have been injected into a front electrode and a rear electrode are drawn so as to be superimposed, and as the injected current increases, the peak at which the intensity of the emitted light becomes the maximum is shifted to light emitted from a heavy positive hole of a ground level, light emitted from a light positive hole of the ground level, and light emitted from a heavy positive hole of a first quantum level. When a high electric current has been injected which leads to a high power, the light emitted from the heavy positive hole of the first quantum level becomes dominant, and the emission spectrum shows the peak which leans to the short wavelength side. FIG. 10 is an emission spectrum appearing when an electric current has been injected into an electrode of the light-emitting side. In the case of low injection, the light emitted from the ground level is dominant, but in the case of high injection by which a high power is obtained, the light emitted from the first quantum level becomes dominant, and a spectral bandwidth results in decreasing.

High current injection is applied to the electrode (front electrode) of the light-emitting side to obtain a high power. In this condition, the front electrode part is in such a state that the current having a high density is injected thereinto, and the resultant spectrum shows that the light emitted from a heavy positive hole of a primary level is dominant. In this state, low current injection is applied to the other electrode (rear electrode) to set the electrode at such a state that an electric current having a low density is injected thereinto and the light emitted from the ground level becomes dominant. In this state, the emitted light is incident on the front electrode part, in which the light emitted from the ground level is dominant, which has been generated in the rear electrode part, thereby induction amplification occurs, and the light having the increased intensity of the light emitted from the ground level is output from the light-outputting side. In other words, the spectrum is superimposed in which the emitted light has been induction-amplified in which the light generated in the rear electrode part and emitted from the ground level is dominant, on the spectrum in which the light emitted from the heavy positive hole of the primary level is dominant, which is obtained by the current injection to the front electrode. Thereby, the emitted light having the high power and showing the broadband spectrum is obtained.

### Exemplary Embodiment 4

As Exemplary Embodiment 4, a structure example of an optical coherence tomography apparatus (OCT apparatus) which employs the super luminescent diode (SLD) of the present invention as the optical source will be described with reference to FIG. 12. The OCT apparatus illustrated in FIG. 12 includes fundamentally an optical source section 1501, a specimen measuring section 1507 which irradiates the specimen with the light from the optical source section and transmits the reflected beam from the specimen portion, and a reference section 1502 which irradiates the reference mirror with the light and transmits the reflected beam from the reference mirror. In addition, the apparatus includes an interference section 1503 which makes two reflected beams interfere with each other, a photodetector section 1509 which detects the interfering beams that have been obtained by the interference section, and an image processing section 1511 which performs image processing (obtains tomogram) based on the light that has been detected in the photodetector section.

As for the optical source section, the SLD optical source 1501 is connected to a fiber coupler 1503 which constitutes the interference section, through an optical fiber 1510 for light irradiation.

The fiber coupler 1503 of the interference section was configured with a fiber coupler of a single mode having a wavelength band of the optical source, and various fiber couplers were configured with 3 dB couplers.

A reflection mirror 1504 is connected to a fiber 1502 for a light path of reference beams to constitute the reference section, and the fiber 1502 is connected to the fiber coupler 1503.

The measuring section includes a fiber 1505 for a light path of an inspection beam, an irradiating and condensing optical system 1506 and a mirror 1507 for scanning a position to be irradiated, and the fiber 1505 for the light path of the inspection beam is connected to the fiber coupler 1503. In the fiber coupler 1503, a backscattering light which has been generated from the inside and the surface of a substance to be inspected 1514 and a return beam from the reference section interfere with each other to form interfering beams.

A detecting side includes a fiber 1508 for receiving light and the photodetector section 1509 which includes a spectral unit and an array type of photo-detecting unit, and spectrally detects the interfering beams having a broadband emission spectrum, for every wavelength band. A signal processor 1511 converts the light which has been received by the array type of photo-detecting unit in the detecting portion 1509 into a spectroscopic signal, and further subjects the spectroscopic signal to Fourier transformation to acquire depth information on a substance to be tested. The acquired depth information is displayed on an image outputting monitor 1512 as a tomographic image. Here, the signal processor 1511 can be configured with a personal computer and the like, and the image outputting monitor 1512 can be configured with a display screen and the like of a personal computer. For instance, if the SLD optical source apparatus which has been described in Exemplary Embodiment 1 is used as a wavelength variable optical source 1501 of the present exemplary embodiment, the tomographic image information with a high depth resolution can be acquired because this SLD optical source apparatus has a broadband spectrum.

The super luminescent diodes (SLD) having the wide wavelength variable bands, which have been described in the above Exemplary Embodiment 1, Exemplary Embodiment 2 and Exemplary Embodiment 3, can be used as an optical source for optical communications and an optical source for optical measurement.

In a field of the optical communications, the number of wavelengths to be multiplexed can be increased due to the wide wavelength variable band, and in a field of the optical measurement, the tomographic image information with the high depth resolution can be acquired because the super luminescent diode has the broadband spectrum as has been described in Exemplary Embodiment 3.

This OCT apparatus is particularly useful in tomographic image photography in ophthalmology, dentistry, dermatology and the like.

### REFERENCE SIGNS LIST

### Advantageous Effects of Invention

The optical semiconductor device according to the present invention has multiple quantum well structures which are mutually different in at least two out of the composition of the well layer, the width of the well layer and the composition of the barrier layer, and accordingly can broaden the wavelength band of the emitted light.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-215767, filed Sep. 28, 2012, which is hereby incorporated by reference herein in its entirety.

### REFERENCE SIGNS LIST

11 n-type electrode

12 GaAs substrate

13 n-side confining layer

14 MQW active layer

15 p-side confining layer

16 GaAs contact layer

17 p-type electrode

1. An optical semiconductor device comprising:
an active layer including a multiple quantum well structure; and
at least one electrode pair for injecting an electric current into the active layer,
wherein the multiple quantum well structure has a first quantum well and a second quantum well which is different from the first quantum well, and the first quantum well and the second quantum well are mutually different in at least two out of a composition of a well layer, a width of the well layer, and a composition of a barrier layer.

2. The optical semiconductor device according to claim 1, wherein the first quantum well is configured to emit light at a ground level and a first quantum level, and a peak of light emitted from a ground level of the second quantum well exists within the full width at half maximum of a peak of the light emitted from the ground level of the first quantum well.

3. The optical semiconductor device according to claim 1, wherein the first quantum well and the second quantum well are different only in the composition of the well layer and the width of the well layer.

4. The optical semiconductor device according to claim 1, wherein the second quantum well is configured to emit light at the ground level.

5. The optical semiconductor device according to claim 1, wherein the ground levels of each of the first quantum well and the second quantum well have a heavy positive hole and a light positive hole, and a peak of light emitted from the heavy positive hole of the second quantum well exists within the full width at half maximum of a peak of light emitted from the heavy positive hole of the first quantum well.

6. The optical semiconductor device according to claim 1, wherein, in the first quantum well and the second quantum well, the well layers have InₓGa₁₋ₓAs (0<x<1).

7. The optical semiconductor device according to claim 1, wherein at least one electrode of the electrode pair is divided so as to inject independently respective electric currents into a plurality of different regions in the active layer.

8. An optical coherence tomography apparatus comprising:
an optical source section having the optical semiconductor device according to claim 1;
a specimen measuring section configured to irradiate a specimen with light emitted from the optical source section and transmitting a reflected beam from the specimen;
a reference section configured to irradiate a reference mirror with the light emitted from the optical source section and transmitting a reflected beam from the reference mirror;
an interference section configured to make the reflected beam from the specimen measuring section and the reflected beam from the reference section interfere with each other;
a photodetector section configured to detect interfering beams from the interference section; and
an image processing section configured to obtain a tomogram of the specimen based on an intensity of the interfering beams which have been detected in the photodetector section.

9. A driving method of the optical semiconductor device according to claim 1, comprising the step of:
injecting an electric current into the active layer,
wherein the injecting step comprises adjusting an amount of the electric current to be injected into the active layer so as to cause light emission from the first quantum well at the ground level and the first quantum level, and so as to provide the peak of the light emitted from the ground level of the second quantum well within the full width at half maximum of the peak of the light emitted from the ground level of the first quantum well.

10. The driving method of the optical semiconductor device according to claim 9, wherein an electric current is injected into a region on a light-emitting end side of the optical semiconductor device among the plurality of different regions so as to make light emitted from a primary level become dominant, and an electric current is injected into the other current injection regions so as to make light emitted from the ground level become dominant.
